(19) United States
(12) Patent Application Publication
(10) Pub. No.: US 2024/0049383 A1
(43) Pub. Date: Feb. 8, 2024

(54) CONNECTION CARRIER, OPTOELECTRONIC DEVICE AND METHOD FOR PRODUCING A CONNECTION CARRIER

(71) Applicant: ams-OSRAM International GmbH, Regensburg (DE)

(72) Inventors: Sebastian WITTMANN, Regenstauf (DE); Michael BRANDL, Mintraching (DE); Andreas DOBNER, Wenzenbach (DE)

(21) Appl. No.: 18/267,051

(22) PCT Filed: Dec. 8, 2021
(86) PCT No.: PCT/EP2021/084864

§ 371 Date: Jun. 13, 2023

(30) Foreign Application Priority Data
Jan. 5, 2021 (DE) 10 2021 200 044.4

(51) Int. Cl. H05K 1/02; H05K 1/11; H05K 3/40

(52) U.S. Cl. CPC H05K 1/0274; H05K 1/111; H05K 3/4007; H05K 2201/10121; H05K 2201/09681

(57) ABSTRACT

The invention relates to a connection carrier having at least one contact track which is connected in an electrically conductive manner to a contact surface for electrically contacting a semiconductor component, the contact track having a network structure in at least some locations. The invention further relates to a method for producing a connection carrier having contact tracks.

The present application relates to a connection carrier, an optoelectronic device, and a method for producing a connection carrier.

This patent application claims the priority of the German patent application 10 2021 200 044.4, the disclosed content of which is hereby incorporated by reference.

For various applications, light sources are required in or behind or on transparent elements such as glass panels, for example for displaying static or moving images. However, it has been shown that conventional electrical contacting of the individual light sources by means of copper conductor tracks is perceived by the viewer as distracting, in particular including when switched off. As an alternative to copper, transparent conductive oxides can also be used. This means that transparency criteria can be met, but due to the significantly lower electrical conductivity compared to copper, high resolution requirements cannot easily be met at the same time.

One object of the invention is to specify a reliable type of electrical contacting that is not perceived by the human eye as distracting.

This object is achieved, inter alia, by a connection carrier, an optoelectronic device and a method for producing a connection carrier according to the independent patent claims. Advantageous embodiments and practical features are the subject matter of the dependent claims.

A connection carrier with at least one contact track is specified. Typically, the connection carrier has a plurality of such contact tracks.

For example, the contact track is arranged on a substrate of the connection carrier.

For example, the substrate contains a glass or a plastic. The substrate can be mechanically flexible or rigid. For example, the substrate itself, i.e. without the contact track, has a transmission of at least 90% in the visible spectral range.

The contact track is metallic, for example. For example, the contact track contains copper or another metal with a high electrical conductivity.

According to at least one embodiment of the connection carrier, the contact track is connected in an electrically conductive manner to a contact surface for providing an electrical contact to a semiconductor component. The contact surface is a surface on which the electrical contact to the, for example, optoelectronic semiconductor component can be produced.

For example, for external electrical contacting the connection carrier has a connection region with a plurality of connection surfaces. For example, each contact surface is directly or indirectly connected to a connection surface in an electrically conductive manner via a contact track.

According to at least one embodiment of the connection carrier, the contact track has a network structure in at least some locations. The contact track is therefore inherently structured. Within the network structure, for example, there are openings in which the substrate is free of the contact track. For example, in a plan view of the connection carrier at least some of the openings are completely enclosed by material of the contact track. For example, the network structure is formed by network tracks that intersect at some locations and run obliquely or perpendicular to each other.

In at least one embodiment of the connection carrier, the connection carrier has at least one contact track, which is connected in an electrically conductive manner to a contact surface for electrically contacting a semiconductor component, wherein the contact track, at least in some locations, has a network structure with a plurality of network tracks.

By means of the network structure, the width of the contact track, i.e. its transverse extent perpendicular to a longitudinal extension axis, can be widened in comparison to a conventional conductor track, wherein the contact track is not perceptible to the human eye or at least the perceptibility is significantly reduced. For example, a transmission of the connection carrier in the region of the contact track is at least 70% or at least 80% or at least 85%. Thus, the contact track can be distributed over a larger area, thus allowing a homogeneous overall impression of the surface to be achieved.

According to at least one embodiment of the connection carrier, the network structure is formed by network tracks, wherein the network tracks have a width between 2 μm and 20 μm inclusive. For example, the width is between 5 μm and 15 μm inclusive. The greater the width, the greater the current carrying capacity of each individual network track of the network structure for the same network track height. However, if the width is too large, the network tracks could be perceptible to the human eye.

According to at least one embodiment of the connection carrier, the network tracks have a height of between 1 μm and 8 μm inclusive. The greater the height of the network tracks, the greater the current carrying capacity of each individual network track for the same network track width. For example, the height is between 2 μm and 4 μm inclusive. However, the greater the height, the higher the risk that the network tracks will detach from the substrate due to stresses.

For example, the aspect ratio, i.e. a height to width ratio, of the network tracks is between 0.2 and 1.5 inclusive. The higher the aspect ratio, the higher the current carrying capacity of the network tracks can be for the same surface area occupied. However, with increasing aspect ratio, the risk of the network track detaching from the substrate can also increase, for example due to stresses.

According to at least one embodiment of the connection carrier, the network structure formed at least in some locations by first network tracks running parallel to one another and second network tracks running parallel to one another, wherein the first network tracks and the second network tracks run obliquely or perpendicular to each other. For example, the first network tracks and the second network tracks are located at an angle to each other of between 30° and 90° inclusive.

For example, a center distance between adjacent first network tracks and/or adjacent second network tracks is at least 10 μm or at least 20 μm and/or at most 2 mm or at most 1 mm, for example between 50 μm and 800 μm inclusive.

According to at least one embodiment of the connection carrier, in a peripheral region of the network structure and in the direction away from the center of the network structure, a center distance (d1) between adjacent first network tracks and/or between adjacent second network tracks is gradually increased and/or the width (w1) of the network tracks is gradually reduced. The peripheral region of the network structure shows a continuously lower density of the network tracks and/or continuously finer network tracks in the direction away from the center of the network structure. For example, the peripheral region may begin at a distance equal to 50% of the length from the center of the network structure to the outermost first and/or second network tracks of the network structure. Thus, a gray haze and hard edge perceptible to the human eye that might occur between the region with and the region without the network structure can advantageously be significantly reduced. In particular, the transition between the transparent but slightly grayish region with the network structure and the region without the network structure can run continuously, so that no sharply cut-off contrast is noticeable to the human eye. As a result, the network structure appears more transparent and less like a foreign object on the connection carrier.

According to at least one embodiment of the connection carrier, a longitudinal extension axis of the contact track, at least in some locations, is inclined relative to the first network tracks and to the second network tracks. The longitudinal extension axis of the contact track itself may be curved or bent in places. For example, an angle to the first network tracks and to the second network tracks can be at least 20° or at least 30°.

According to at least one embodiment of the connection carrier, the contact surface is a flat electrically conductive region. In this context, for example, flat means that a maximum extent of the contact surface in plan view of the connection carrier in two mutually perpendicular directions is greater than the width of the individual network tracks, for example by at least a factor of 1.5 or by at least a factor of 3. For example, the contact surface has a longitudinal extent in two mutually perpendicular directions of between 3 and 150 μm inclusive, or between 20 and 100 μm inclusive, preferably between 30 and 60 μm. The longitudinal extent can also be advantageously chosen such that it is at least as large as a center distance between adjacent first network tracks and/or adjacent second network tracks.

According to at least one embodiment of the connection carrier, the contact surface overlaps with at least two network tracks of the network structure. For example, the contact surface may have a continuation that extends away from the contact surface. The continuation preferably has a larger width than the network tracks in the surrounding area. This enables the reliability of the electrical contacting to be increased. For example, the length of the continuation is at least as large as a distance between the first network tracks and/or a distance between the second network tracks. The reliability of the electrical connection of the contact surface to the network structure can thus be increased.

According to at least one embodiment of the connection carrier, the contact surface does not overlap with the adjacent first network tracks and/or with the adjacent second network tracks of the network structure. For example, the contact surface can be arranged outside the network structure on the connection carrier. The continuation preferably extends between the contact surface and the network structure. The continuation connects the contact surface to the network structure. Preferably, the continuation overlaps with the network structure or at least adjoins the network structure. Alternatively, or in addition, the continuation may have additional branches that extend away from the continuation, overlapping with or at least adjoining the network structure. Advantageously, semiconductor components can thus also be arranged outside the network structure, ensuring a reliable electrical contacting by means of the continuation.

According to at least one embodiment of the connection carrier, the continuation has a width of between 5 μm and 50 μm inclusive. Preferably, the width is between 10 μm and 25 μm inclusive. Preferably, the width of the continuation is at least 20% larger than the width of the first and/or the second network tracks. A reliable mechanical adhesion of the continuation to the connection carrier can be ensured by using a width of 15 μm, for example. The greater the width, the greater the current carrying capacity of each continuation for the same height. However, if the width is too large, the continuation could be visible to the human eye.

According to at least one embodiment of the connection carrier, the network structure along the contact track forms at least two separate current paths within the contact track. In this context, separate current paths means in particular that the current paths can individually form an electrically conductive connection along the contact track, even if another current path is interrupted. Preferably, this applies at any point along the longitudinal extension axis of the contact track. The separate current paths therefore use different subregions of the network structure within the same contact track and are connected to each other in an electrically conductive manner. This allows redundancy to be achieved for the current supply. The risk that a defect in a network track, for example caused by small particles during production, might lead to failure of the entire contact track is thus eliminated or at least reduced.

According to at least one embodiment of the connection carrier, the contact track has a reflection-reducing coating in at least some locations. In particular, the network structure has the reflection-reducing coating. The reflection-reducing coating is intended in particular to reduce specular reflection at the contact track. For example, the contact track is blackened or at least darkened by the reflection-reducing coating. The perceptibility of the contact track by the human eye can thus be further reduced.

For example, the reflection-reducing coating contains palladium or molybdenum or copper nitride.

According to at least one embodiment of the connection carrier, the contact track is subdivided into two subregions at a virtual intersection point with a further contact track, wherein the subregions are connected to each other via an electrically conductive bridge, which is electrically insulated from the further contact track. In a plan view of the connection carrier, the electrically conductive bridge overlaps with the other contact track, but is electrically insulated from the other contact track, for example by an insulator. Such an electrically conductive bridge can be produced, for example, by an additive method, for example, by a printing method, a jetting method, a method for producing a planar contact or by a transfer method, such as a laser-induced forward transfer method (LIFT).

By means of such electrically conductive bridges, intersecting electrical contacts, as can be produced in a conventional circuit board with multiple conductor layers, can be achieved using only one layer for the network structure.

According to at least one embodiment of the connection carrier, at least one contact track provides an electrical contacting of the semiconductor component and/or at least one contact track provides a capacitive tactile sensor function. The at least one contact track which provides the capacitive tactile sensor function can be used for controlling the semiconductor component. One or more contact tracks can form an electrode used for the capacitive tactile sensor function. The connection carrier advantageously has a plurality of electrodes arranged side by side.

In particular, at least one contact track or at least one subregion of the network structure can provide a surface that can be used for a capacitive tactile sensor function. For example, the at least one contact track or the subregion of the network structure can provide a surface that functions as a button or sensor surface in order to electrically switch the semiconductor component and/or other functions associated with the button or the sensor surface. In particular, a button or a sensor surface may be designed to switch the semiconductor component on or off or to control the intensity of the semiconductor component. Alternatively, or in addition, the button or the sensor surface may be designed to switch the functions associated with the button or the sensor surface. In particular, such functions can be switching a motor or an actuator or a sensor on and off. Advantageously, such buttons or sensor surfaces can be used on windowpanes or in the interior of a car to switch indicators, display panels, motors, actuators or sensors.

According to at least one embodiment of the connection carrier, the button or the sensor surface is arranged on a substrate, such as a glass plate or a plastic film. In particular, the substrate is transparent or semi-transparent.

According to at least one embodiment of the connection carrier, at least one contact track is arranged on a first side and/or on a second side of the connection carrier facing away from the first side. The network structure can be structured in a plurality of contact tracks. The contact track may also be electrically connected from at least one connection surface. For example, one contact track can form an electrode or multiple contact tracks in combination can form a common electrode. The connection carrier advantageously comprises a plurality of electrodes arranged side by side, which can be used for a capacitive tactile sensor function.

For example, a contact track providing a capacitive tactile sensor function can be electrically contacted at four connections of four connection surfaces. For example, the four connection surfaces can connect one contact track at four corners or four sides of a surface of the network structure. Advantageously, this can be used to provide a surface-capacitive tactile sensor function (Surface Capacitive Touch).

Alternatively, or in addition, the network structure may be structured into multiple arbitrarily shaped contact tracks, which provide a capacitive tactile sensor function. In this case, a first contact track or a combination of contact tracks can form a first electrode and a second contact track or a combination of contact tracks can form a second electrode. Alternatively, the connection carrier may have more than two electrodes. The electrodes can be arranged adjacent to each other on one side of the connection carrier and are thus electrically insulated from each other by a gap in the network structure. If the electrode is formed by a combination of contact tracks, the contact tracks are advantageously rectangular and oriented adjacent and parallel to each other. In this case each contact track is electrically insulated from an adjacent contact track by an intervening gap. For example, each contact track is electrically contacted at two connections of two connection surfaces. Advantageously, the connections of the connection surfaces are arranged as far away from each other as possible on a longitudinal extension axis of the contact track.

Alternatively, or in addition, the network structure may be structured in a plurality of contact tracks and arranged on two sides facing away from the connection carrier. For example, the capacitive tactile sensor function can be provided by arranging a plurality of parallel oriented contact tracks on a first side of the connection carrier and arranging a plurality of parallel oriented contact tracks on a second side of the connection carrier facing away from the first side. In this case, the contact tracks on the first side and the contact tracks on the second side facing away from the first side may be arranged perpendicular to each other on the connection carrier. In particular, the contact tracks on the first side and the contact tracks on a second side of the connection carrier facing away from the first side are arranged directly on top of each other. Each contact track providing the capacitive tactile sensor function is thus electrically contacted by at least two connection surfaces. Advantageously, multiple contact tracks in combination can form a common electrode. In particular, a first electrode can be arranged on a first side of the connection carrier and a second electrode can be arranged on a second side facing away from the first side. For example, the connection carrier may comprise a plurality of differently poled electrodes. An electrode can be electrically connected to a ground. For example, the connection carrier may comprise a plurality of first and second electrodes. Alternatively, the connection carrier can also comprise a third electrode or even further electrodes. Advantageously, a projected-capacitive tactile sensor function (Projective Capacitive Touch or PCAP) can be provided.

Furthermore, an optoelectronic device with a connection carrier described above is specified. The optoelectronic device further comprises at least one optoelectronic semiconductor component, wherein the optoelectronic semiconductor component is connected in an electrically conductive manner to at least two contact surfaces.

For example, the optoelectronic device has a connection region, for example at an edge of the optoelectronic device at which the optoelectronic device is externally electrically contactable. For example, each contact surface is directly or at least indirectly connected in an electrically conductive manner to at least one connection surface of the connection region via a contact track.

The optoelectronic semiconductor component is, for example, a luminescent diode, such as a light-emitting diode, or a sensor.

Typically, the optoelectronic device comprises a plurality of optoelectronic semiconductor components, for example, at least 100 optoelectronic semiconductor components or at least 1000 optoelectronic semiconductor components. In addition, further components may be provided, for example passive electronic components such as resistors, sensors or capacitors, or active electronic components such as integrated circuits. The optoelectronic semiconductor components can be externally electrically contactable either individually or in groups via a connection surface of the connection region. For example, at least some of the optoelectronic semiconductor components are electrically connected in series or electrically in parallel with each other by means of the contact tracks.

According to at least one embodiment of the optoelectronic device, electrical connections of the optoelectronic semiconductor component are arranged on a side facing the connection carrier. For example, the contact surfaces of the connection carrier overlap with the associated optoelectronic semiconductor component. For example, the optoelectronic semiconductor component is designed as a flip-chip component, in which the electrical connections required for the electrical contacting are arranged on the side facing the connection carrier.

The electrical contacting of the electrical connections with the associated connection surfaces can be effected, for example, via a connection layer, such as an electrically conductive adhesive layer or a solder layer.

The optoelectronic semiconductor component may also comprise more than two electrical connections, for example, for electrically activating separate active regions. For example, the active regions can generate radiation in different spectral ranges.

According to at least one embodiment of the optoelectronic device, at least one electrical connection of the optoelectronic semiconductor component is arranged on a side facing away from the connection carrier and connected to the contact surface in an electrically conductive manner via a contact conductor. All electrical connections of the optoelectronic semiconductor component can also be connected in an electrically conductive manner to the associated contact surface via a contact conductor. Such a contact conductor can be applied by an additive method, for example, by a printing method, a jetting method, a method for producing a planar contact or by a transfer method, such as a laser-induced transfer method.

In this case, the electrical contacting of the optoelectronic semiconductor component in the production of the optoelectronic device can also only take place after the optoelectronic semiconductor component is already attached to the connection carrier. Such electrical contacting of the optoelectronic semiconductor components can also be used during the production of the optoelectronic device to replace non-functional optoelectronic semiconductor components during the production of the optoelectronic device, for example after a test step.

Furthermore, a method for producing a connection carrier with contact tracks is specified. The method is particularly suitable for producing a connection carrier described above. The features described in connection with the connection carrier can therefore also be applied to the method and vice versa.

According to at least one embodiment of the method, a substrate is provided and contact tracks, which have a network structure, at least in some locations, are formed.

According to at least one embodiment of the method, a continuous network structure is formed on the substrate before the formation of the contact tracks and the network structure is structured in the contact tracks when the contact tracks are formed. The network structure initially provided thus does not yet have a specific shape for the specific configuration of the contact tracks.

According to at least one embodiment of the method, the network structure and the contact tracks are formed in a common method step. In this case, the network structure can already be specifically adapted to the specific profile of the contact tracks to be produced.

According to at least one embodiment of the method, contact surfaces are formed, which are connected in an electrically conductive manner to a contact track in each case.

The contact surfaces can be formed before or after the structuring of the network structure into the contact tracks. For example, the contact surfaces can be applied in a structured form by means of a lithographic structuring process.

To produce an optoelectronic device described above, the connection carrier thus produced can be populated with optoelectronic semiconductor components.

Further advantages and advantageous features of the invention can be found in the following description of the exemplary embodiments in conjunction connection with the drawings.

In the drawings:

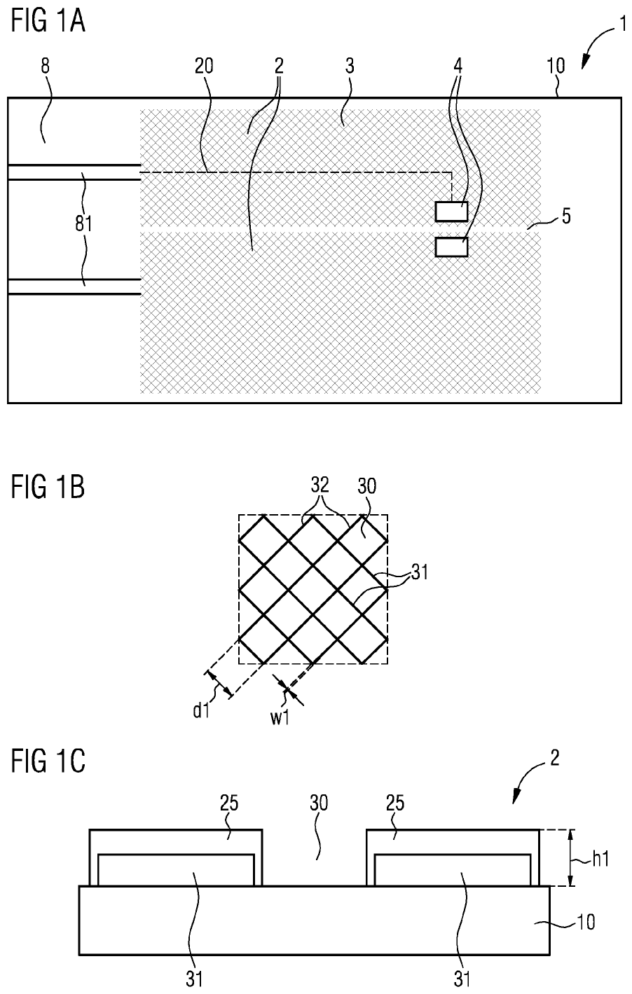

FIG. 1A shows an exemplary embodiment of a connection carrier in a schematic plan view;

FIG. 1B shows an enlarged drawing of a detail of FIG. 1A;

FIG. 1C shows an enlarged drawing of a detail of the connection carrier of figure LA in a schematic sectional view;

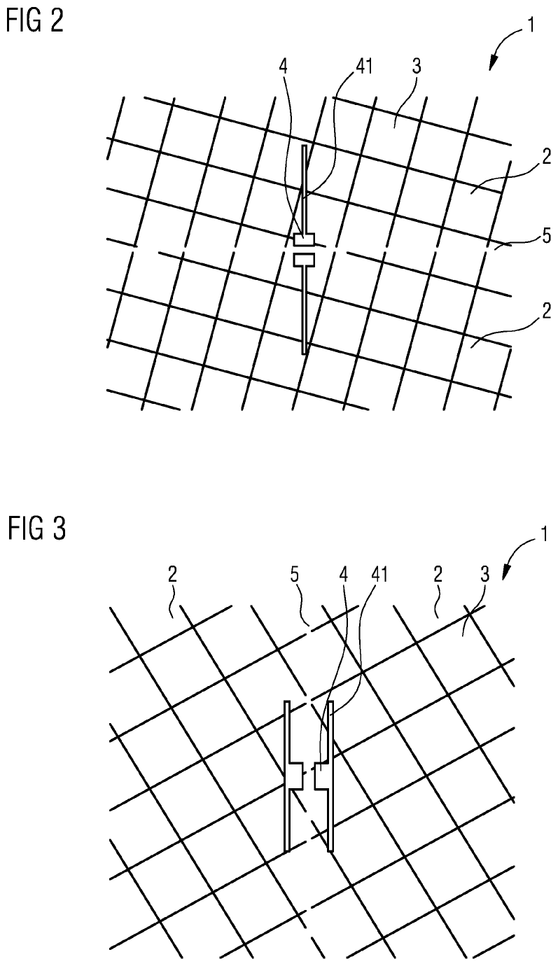

FIGS. 2, 3 and 4 each show an exemplary embodiment of a connection carrier in a schematic plan view;

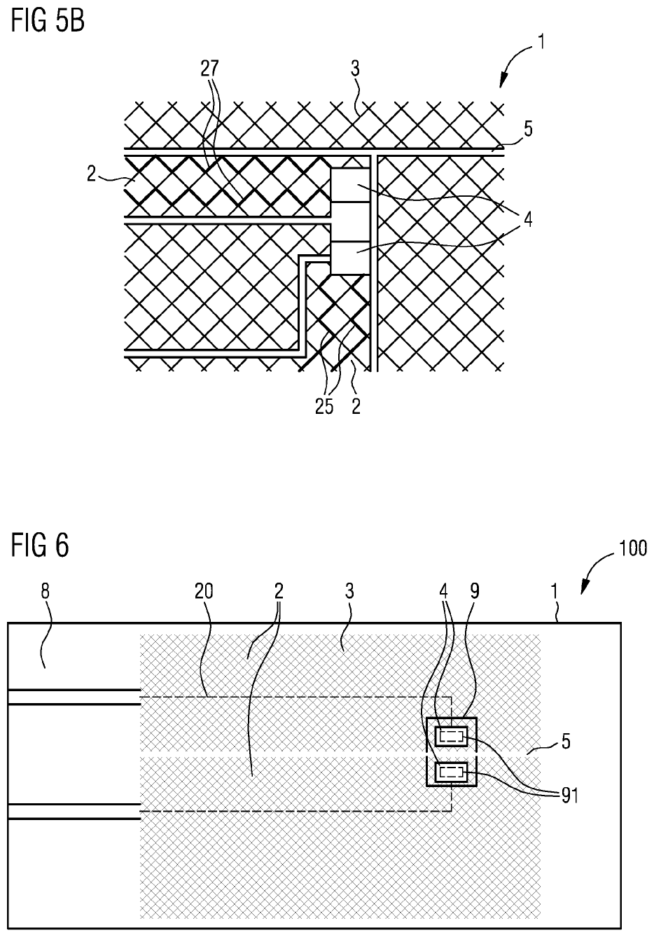

FIGS. 5A and 5B each show an exemplary embodiment of a connection carrier in a schematic plan view;

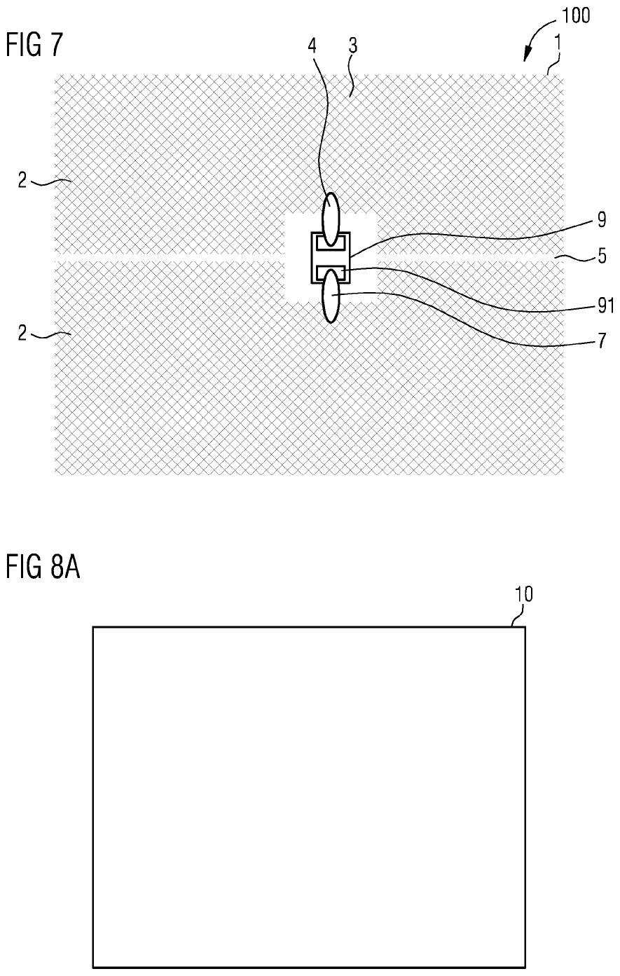

FIGS. 6 and 7 each show an exemplary embodiment of an optoelectronic device in plan view;

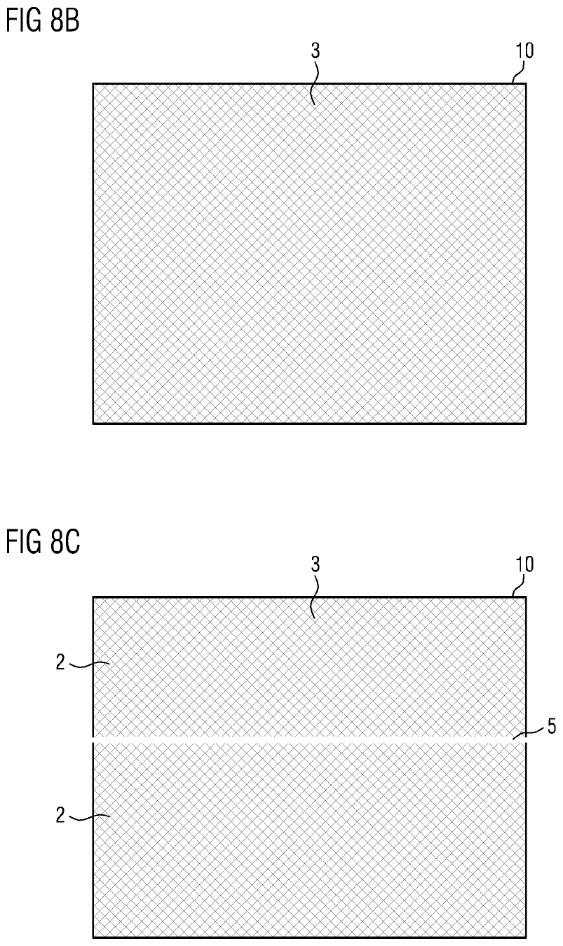

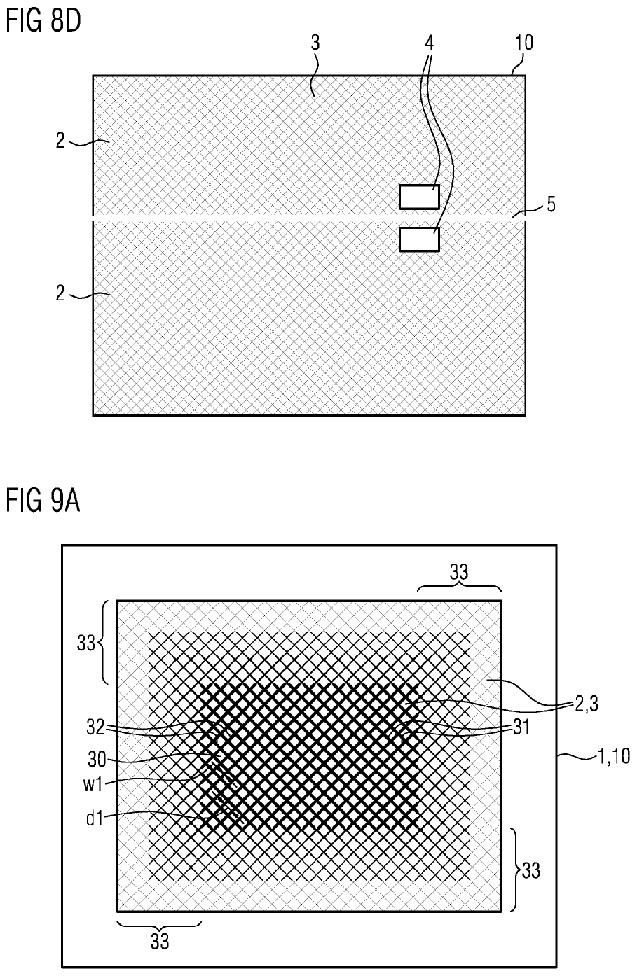

FIGS. 8A, 8B, 8C and 8D each show an exemplary embodiment of a method for producing a connection carrier using intermediate steps shown schematically in plan view;

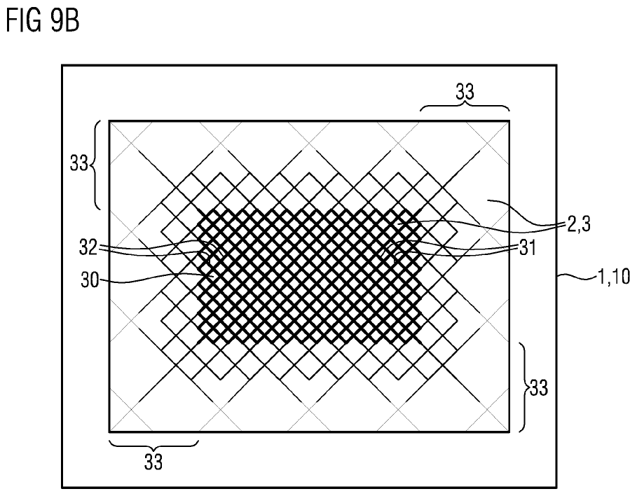

FIG. 9A shows an exemplary embodiment of a connection carrier in a schematic plan view;

FIG. 9B shows an exemplary embodiment of a connection carrier in a schematic plan view;

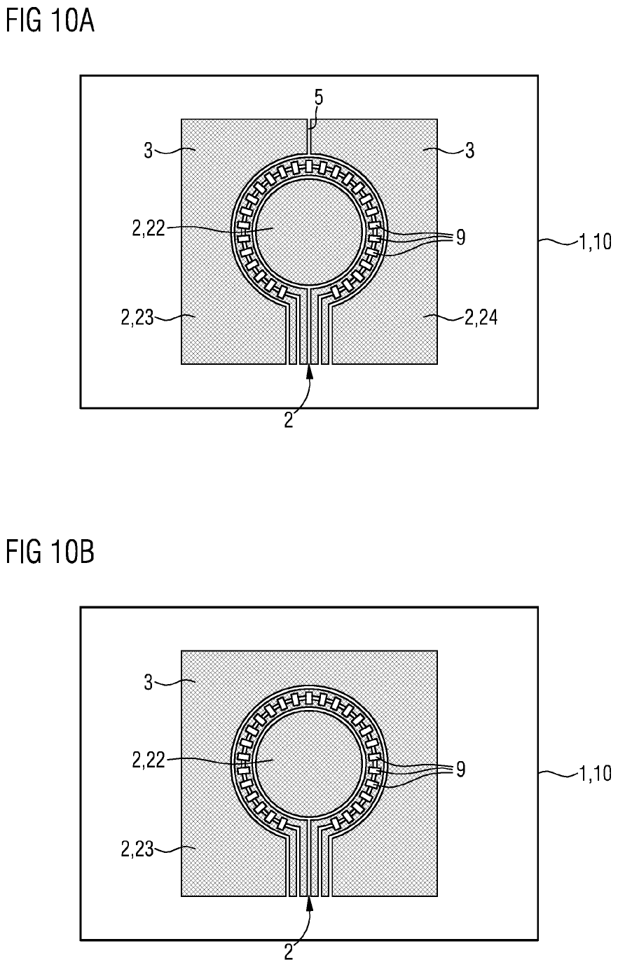

FIGS. 10A and 10B each show an exemplary embodiment of a connection carrier in a schematic plan view; and

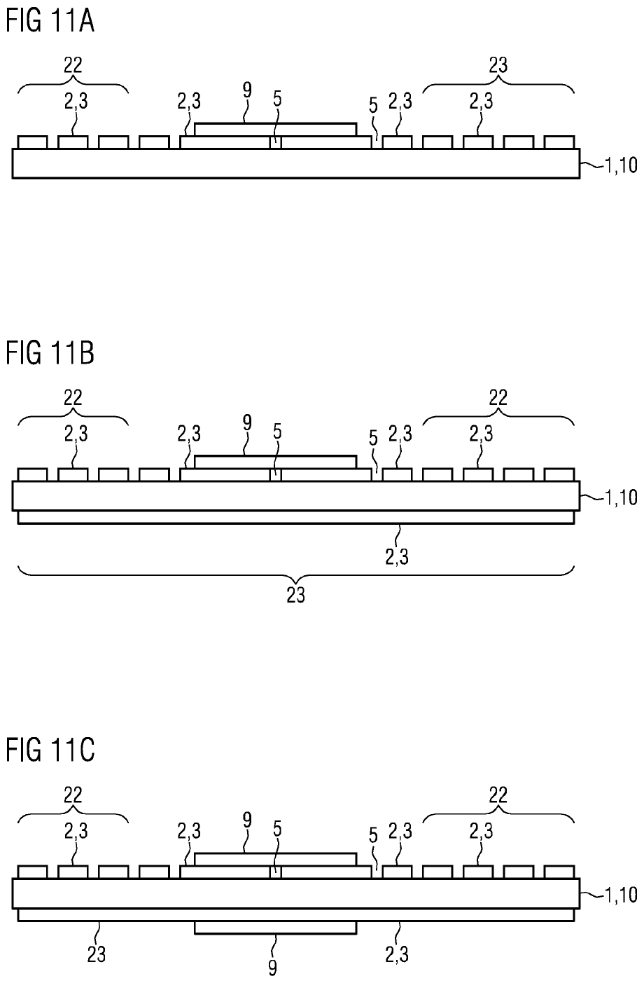

FIGS. 11A to 11C each show an exemplary embodiment of a connection carrier in a schematic sectional view.

Identical, similar or equivalently functioning elements are labeled with the same reference signs in the figures.

The figures are all schematic representations and therefore not necessarily true to scale. Instead, individual elements and in particular layer thicknesses can be shown exaggerated in size for better visualization and/or improved understanding.

The exemplary embodiment shown in FIG. 1A has a connection carrier 1 with contact tracks 2, wherein the contact tracks 2 are each connected in an electrically conductive manner to a contact surface 4 for electrically contacting a semiconductor component. The contact tracks 2 each have a network structure 3 in some locations. The contact tracks 2 are arranged on a substrate 10 of the connection carrier 1.

For example, the contact tracks 2 each connect at least one contact surface 4 to a connection surface 81 of a connection region 8 of the connection carrier 1.

The connection region 8 is located, for example, on an edge region of the connection carrier 1 and is used for the external electrical contacting of the connection carrier. The network structure 3 in the illustrated exemplary embodiment is formed by first network tracks 31 and second network tracks 32, wherein the first network tracks 31 each run parallel to each other and the second network tracks 32 each run parallel to each other. The first network tracks 31 and the second network tracks 32 run obliquely or perpendicular to each other, in the illustrated exemplary embodiment perpendicular.

However, a different angle may also be applied. Between the network tracks 31, 32, openings 30 are formed in which the substrate 10 is free of material for the contact track.

Purely for simplicity of illustration the connection carrier 1 has only two contact tracks 2, each having one contact surface 4, wherein the contact surfaces 4 are designed for electrically contacting a semiconductor component, for example an optoelectronic semiconductor component. Typically, the connection carrier 1 has a plurality of such contact tracks 2, wherein the contact tracks 2 are designed, for example, for electrically contacting 100 or more semiconductor components.

The contact tracks 2 are electrically insulated from each other by an intervening gap 5. In comparison to a conventionally produced contact track in the form of a continuous solid conductor track, the contact tracks 2 can have a comparatively large transverse extent perpendicular to their longitudinal extension axis 20 in plan view of the connection carrier 1, without the contact tracks 2 being visible to the human eye. The electrical contacting via the contact tracks 2 can therefore be distributed over a comparatively large area, resulting in a homogeneous overall impression to the human eye.

In particular, the gaps 5 can also be formed sufficiently narrow that they are not perceptible.

The longitudinal extension axis 20 of the contact track 2 runs, at least in some locations, obliquely to the first network tracks 31 and obliquely to the second network tracks 32, for example at an angle of 45° to each of these network tracks 31, 32. For example, the network tracks 31, 32 have a width w1 between 2 μm and 20 μm inclusive, for example between 5 μm and 15 μm inclusive.

For example, perpendicular to a main extension plane of the connection carrier 1, the network tracks have a height h1 between 1 μm and 8 μm inclusive, for example between 2 μm and 4 μm inclusive. An aspect ratio of the network tracks is between 0.2 and 1.5 inclusive, for example.

For example, a center distance d1 between adjacent first network tracks 31 and/or between adjacent second network tracks 32 is between 50 μm and 800 μm inclusive.

The contact surfaces 4 are in each case flat electrically conductive regions with a maximum extent along two mutually perpendicular directions, each of which is larger than the width w1 of a single network track.

Furthermore, the connection surfaces 81 in the connection region 8 can also be formed by flat electrically conductive regions. This can facilitate the external electrical contactability of the connection carrier 1.

A suitable option for the substrate 10, for example, is a mechanically rigid substrate, e.g. in the form of a disk or plate, or a mechanically flexible substrate, e.g. in the form of a film. The substrate 10 is electrically insulating. For example, the substrate 10 is transparent in the visible spectral range. For example, the substrate 10 contains a glass or a plastic such as polyethylene, polyimide, polyethylene terephthalate, polyethylene naphthalate or polyacrylic.

The contact tracks 2 are metallic, for example. For example, the contact tracks 2 contain copper or another metal with high electrical conductivity. To avoid or at least reduce specular reflection, the contact track 2 may have a reflection-reducing coating 25. This is shown schematically in the sectional view of FIG. 1C. For example, copper-based contact tracks can be blackened by means of molybdenum or palladium or copper nitride, in particular in the region of the network structure 3 with the network tracks 31, 32.

The exemplary embodiments shown in FIGS. 2 and 3 correspond essentially to the exemplary embodiment described in connection with FIGS. 1A to 1C. In contrast to the latter, the contact surface 4 has a continuation 41. Along one direction, a maximum extent of the continuation 41 is greater than the center distance d1 between the network tracks 31, 32. With such a continuation 41, the reliability of the electrical contacting of the contact surface 4 to the network structure 3 of the contact track 2 can be increased, since an electrically conductive contact exists between the contact surface 4 and the network structure 3 at multiple locations.

In the exemplary embodiment shown in FIG. 2, the continuation 41 extends away from the contact surface 4 on a lateral surface of the contact surface 4. The continuation 41 is formed on a lateral surface of the contact surface 4, which faces away from the nearest contact surface 4 of another contact track 2.

In the exemplary embodiment shown in FIG. 3, the continuation 41 extends beyond the contact surface 4 on two opposite lateral surfaces of the contact surface 4.

Of course, the shape or the number of continuations 41 can be varied within wide limits. Such a continuation is particularly expedient if the size of the contact surface 4 is less than or equal to the center distance d1 between the network tracks 31, 32 at least along one direction.

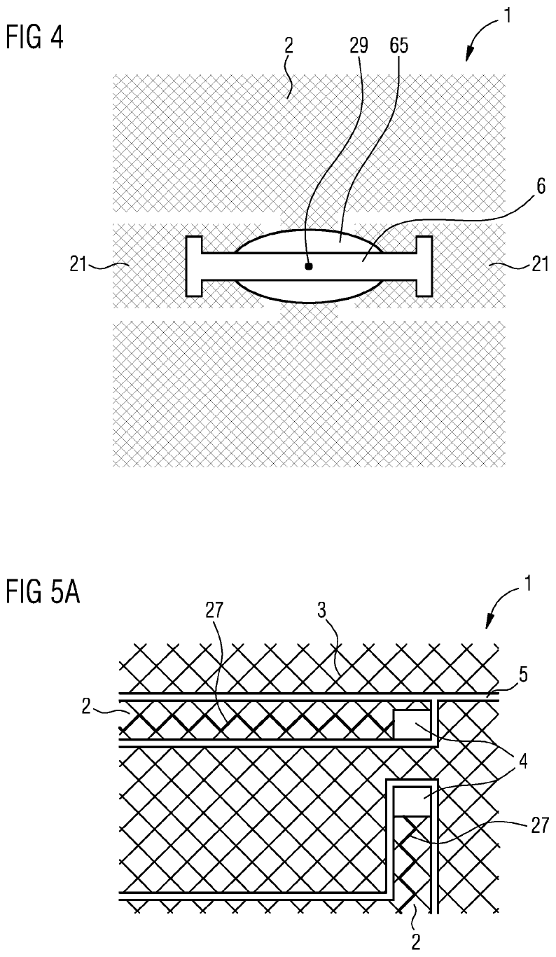

The exemplary embodiment shown in FIG. 4 corresponds essentially to the exemplary embodiment shown in connection with the FIGS. 1A to 1C. In contrast to this, a contact track 2 is subdivided into two sub-regions 21 at a virtual intersection point 29 with a further contact track 2. The subregions 21 are connected to each other by means of an electrically conductive bridge 6. In plan view of the connection carrier 1, the bridge 6 overlaps with the further contact track 2 but is electrically insulated from the latter by means of an insulator 65. By means of such bridges applied by additive manufacturing, intersecting contact tracks 2 with a network structure 3 can be realized in only one layer.

FIGS. 5A and 5B illustrate the current flow within the contact tracks 2.

FIG. 5A shows the extreme case that the contact tracks 2 are so narrow that along the longitudinal extension axis 20 of the contact tracks 2 only one continuous current path 27 results in each case, which is illustrated by the zigzag curve shown. Although this is possible in principle, there is a risk of failure if the grid structure 3 has a defect along this current path 27. Preferably, the contact tracks 2, as shown in FIG. 5B, are each designed in such a way that at least two separate current paths 27 are formed along the contact tracks 2 by means of the network structure 3 within the respective contact track 2. If one of the current paths 27 is interrupted, an electrically conductive connection still exists via the other current path 27. Preferably, such redundancy exists at any point along the longitudinal extension axis 20 of the contact track 2 from the contact surface 4 to the associated connection surface 81.

FIG. 6 shows an exemplary embodiment of an optoelectronic device 100, wherein the connection carrier 1 is formed as described in connection with FIGS. 1A to 1C.

The optoelectronic device 100 comprises an optoelectronic semiconductor component 9, wherein the optoelectronic semiconductor component 9 is connected in an electrically conductive manner to at least two contact surfaces 4. In the illustrated exemplary embodiment, the optoelectronic semiconductor component 9 has electrical connections 91 on a side facing the connection carrier 1. For example, the optoelectronic semiconductor component 9 is a light-emitting diode in flip-chip geometry. In plan view of the optoelectronic device 100, the optoelectronic semiconductor component 9 overlaps with the associated contact surfaces 4 of the connection carrier 1. The optoelectronic device 100 can comprise a plurality of optoelectronic semiconductor components, for example light-emitting diodes or detectors and optionally further electronic components, which are connected in an electrically conductive manner to associated contact surfaces 4 of the connection carrier 1.

Such an optoelectronic device 100 can be applied, for example, on a glass plate or embedded between two glass plates. The glass plate can be used, for example, for a building or a motor vehicle. Placement behind a transparent or semi-transparent plastic carrier is also conceivable in order to illuminate the carrier.

The exemplary embodiment of an optoelectronic device shown in FIG. 7 corresponds essentially to the optoelectronic device 100 described in connection with FIG. 6. In contrast to this, the optoelectronic semiconductor component 9 has electrical connections 91 on a side facing away from the connection carrier 1. The electrical connections 91 are connected in an electrically conductive manner to the contact surfaces 4 via a contact conductor 7. In this case, the contact surface 4 can also be formed by the network structure 3 of the contact track 2. In the production of the optoelectronic device 100, the contact conductors 7 can be applied by an additive method after the optoelectronic semiconductor components 9 are attached to the connection carrier 1.

Of course, semiconductor components in the geometries described in connection with FIGS. 6 and 7 and the associated type of electrical contacting can also be combined with each other within one optoelectronic device 100.

An exemplary embodiment of a method for producing a connection carrier is schematically illustrated in FIGS. 8A to 8D. As shown in FIG. 8A, a substrate 10 is provided. A network structure 3 is formed on the substrate 10 (FIG. 8B). The network structure 3 can extend uniformly over a majority of the substrate 10 or also over the entire substrate 10. The material for the network structure 3 can be applied to the substrate 10 by sputtering or evaporation, for example, and if necessary, additionally by galvanic reinforcement.

Subsequently, contact tracks 2 are formed, which have the network structure 3 at least in some locations. For this purpose, the network structure 3 can be removed in places so that there are gaps 5 between the contact tracks 2. This can be carried out, for example, by laser ablation or by chemical material removal.

As shown in FIG. 8D, contact surfaces 4 are formed on the substrate 10. The contact surfaces 4 each overlap with the network structure of the associated contact track 2. Of course, the contact surfaces 4 can also be formed before the structuring into contact tracks 2 is carried out. In this exemplary embodiment, the network structure 3 is initially formed largely independently of the shape of the contact tracks 2 to be produced, before a structuring into contact tracks 2 is carried out. Deviating from this, the network structure 3 can already be designed in a structured form for the contact tracks 2. In this case, the network structure can also be specifically matched to the shape of the contact tracks to be produced.

The exemplary embodiment shown in FIG. 9A shows a connection carrier 1 having a network structure 3. The connection carrier 1 comprises semiconductor devices 9 on the network structure 3 (not shown in FIG. 9A). The network structure 3 has a peripheral region 33. In the peripheral region 33 of the network structure 3 and in the direction away from the center of the network structure 3, the center distance (d1) between adjacent first network tracks 31 and the center distance (d1) between adjacent second network tracks 32 is constant, wherein the width (w1) of the network tracks 31 and 32 is gradually reduced. The peripheral region 33 shows progressively thinner network tracks 31 and 32 in the direction away from the center of the network structure 3.

The exemplary embodiment shown in FIG. 9B corresponds essentially to the exemplary embodiment shown in FIG. 9A. In contrast, in the peripheral region 33 and in the direction away from the center of the network structure 3, the center distance (d1) between adjacent first network tracks 31 and the center distance (d1) between adjacent second network tracks 32 is gradually increased. The peripheral region 33 of the network structure 3 shows a progressively lower density of the network tracks 31 and 32 and progressively thinner network tracks 31 and 32 in the direction away from the center of the network structure 3. The connection carrier 1 in FIG. 9B has semiconductor components 9 on the network structure 3 (not shown in FIG. 9B).

Alternatively, the width (w1) of the network tracks 31 and 32 can be constant, wherein in the peripheral region 33 and in the direction away from the center of the network structure 3, the center distance (d1) between adjacent first network tracks 31 and the center distance (d1) between adjacent second network tracks 32 is gradually increased.

As shown in both FIGS. 9A and 9B, the region with the network structure 3 advantageously passes continuously via the peripheral region 33 into the region without a network structure. As a result, no stark contrast is noticeable to the human eye and the network structure appears more transparent and less like a foreign object on the connection carrier 1.

The exemplary embodiment shown in FIG. 10A has a connection carrier 1 having a network structure 3. The network structure 3 is structured by means of intervening gaps 5 into multiple contact tracks 2. The semiconductor components 9 are electrically contacted by means of two contact tracks 2. In addition, three contact surfaces 2 each form a first 22, a second 23 and a third 24 electrode, which can be used for a capacitive tactile sensor function. The connection carrier 1 has connection surfaces 81 for the respective contact surfaces 2 (not shown in FIG. 10A).

The contact tracks 2, which provide the electrical contacting of the semiconductor components 9, and the first 22, second 23 and third 24 electrode are arranged on the same surface of the connection carrier 1 and the substrate 10 respectively. The first electrode 22 is formed by a circular surface. The two contact surfaces 2, which provide the electrical contacting of the semiconductor devices 9, are also arranged around the first electrode 22. In this case, the first electrode 22 and the two contact surfaces 2, which provide the electrical contacting of the semiconductor component 9, are electrically insulated from each other by intervening gaps 5. The contact surfaces 2, which provide the electrical contacting of the semiconductor components 9, are each formed by an annular surface and two incoming conductive surfaces of the network structure 3. A continuous contact surface 2 is thus formed. The two incoming conducting surfaces extend in a straight line and parallel to each other onto the annular surface.

Around the first electrode 22 and the two contact surfaces 2, which provide the electrical contacting of the semiconductor components 9, two further contact surfaces 2 are arranged, with one contact surface 2 forming a second electrode 23 and one contact surface 2 forming a third electrode 24. At the same time, the second electrode 23 and the third electrode 24 together form a rectangle around the first electrode 22 and the two contact surfaces 2 which provide the electrical contacting of the semiconductor components 9. The second 23 and third electrode 24 are electrically insulated from each other by a gap 5 on the side opposite the incoming surfaces of the two contact surfaces 2, which provide the electrical contacting of the semiconductor component.

The gap 5 which separates the second electrode 23 from the third electrode 24 runs vertically in a straight line on the two annular surfaces of the contact surfaces 2 that provide the electrical contacting of the semiconductor components 9. The laterally adjacent first electrode 22, the second electrode 23 and the third electrode 24 can be advantageously used for a capacitive tactile sensor function. For example, the exemplary embodiment shown in FIG. 10A could be formed as a button or a sensor surface.

The exemplary embodiment shown in FIG. 10B corresponds essentially to the exemplary embodiment described in connection with FIG. 10A. In contrast to this, the connection carrier 1 has two contact surfaces 2, which form a first electrode 22 and a second electrode 23. In this case, the first electrode 22 has a circular shape. Furthermore, the second electrode 23 is arranged around the first electrode 22 and the two contact surfaces 2 which provide the electrical contacting of the semiconductor components 9. The second electrode 23 thus forms a rectangular surface, which is interrupted by the first electrode 22 and the two contact surfaces 2, which provide the electrical contacting of the semiconductor components 9.

To simplify the illustration, the contact surfaces 2 of the connection carrier 1 in FIG. 10B do not show any connection surfaces 81, continuations 41 or contact surfaces 4.

The first electrode 22 and the laterally adjacent second electrode 23 can be advantageously used for a capacitive tactile sensor function. For example, the exemplary embodiment shown in FIG. 10B could be formed as a button or a sensor surface.

The exemplary embodiment shown in FIG. 11A has a connection carrier 1 having a network structure 3. The network structure 3 is structured into multiple contact tracks 2 arranged in parallel. Between each adjacent contact track 2 an intervening gap 5 is arranged, which electrically insulates the neighboring contact tracks 2 from each other.

In particular, two contact tracks 2 provide electrical contacting of the semiconductor component 9. The semiconductor component 9 is arranged on the two contact tracks 2 which provide the electrical contacting. To simplify the illustration, the two contact tracks 2 in FIG. 11A providing the electrical contacting of the semiconductor component 9 have no contact surfaces 4.

In addition to the two contact tracks 2 providing the electrical contacting of the semiconductor component 9, further contact tracks 2 are arranged on the connection carrier 1. In this case, at least one further contact track 2 forms an electrical conductor on the connection carrier 1. The exemplary embodiment shown in FIG. 11A further comprises, in addition to the two contact tracks 2 providing the electrical contacting of the semiconductor component 9, a plurality of parallel contact tracks 2, which in combination form a first electrode 22 and a second electrode 23. The two contact tracks 2 providing the electrical contacting of the semiconductor component 9 are in this case arranged between the first electrode and second electrode 23. The first electrode 22 and the second electrode 23 can be advantageously used for a capacitive tactile sensor function.

To simplify the illustration, FIG. 11A shows the contact tracks 2 without connection surfaces 81. In this case, the contact track 2 providing the electrical contacting of the semiconductor component 9 has exactly one connection surface 81, as shown in FIG. 1A.

The contact tracks 2, which provide a capacitive tactile sensor function, can have at least two connection surfaces 81. In particular, each contact track 2 providing a capacitive tactile sensor function has exactly two connection surfaces 81. In this case, a first connection surface 81 of the contact track 2 contacts a first connection 91 and a second connection surface 81 of the contact track 2 contacts a second connection 91, wherein the first and second connection 91 are arranged as far apart from each other as possible on a longitudinal extension axis 20 of the contact track 2.

Alternatively, or in addition thereto, the contact track 2 providing a capacitive tactile sensor function can be electrically contacted at four connections 91 of four connection surfaces 81. For example, the four connection surfaces 81 can connect one contact track 2 at four corners or on four sides.

The exemplary embodiment shown in FIG. 11B corresponds essentially to the exemplary embodiment described in connection with FIG. 11A. In contrast, the connection carrier 1 has a first network structure 3 on a first side and a second network structure 3 on a second side of the connection carrier 1. The first and second network structure 3 are structured into multiple contact tracks 2 oriented in parallel. The contact tracks 2 on the first side are aligned perpendicular to the contact tracks 2 on the second side of the connection carrier 1. The first side of the connection carrier 1 is located opposite the second side of the connection carrier 1. In particular, a plurality of parallel contact tracks 2 thus form a first electrode 22 and a further first electrode 22 on the first side. The first electrode 22 and the further first electrode 22 are arranged on the same side and in the same plane on the connection carrier 1. Further, the contact tracks 2, which provide the electrical contacting of the semiconductor component 9, are arranged between the first electrode 22 and the further first electrode 22 on the connection carrier 1. The contact tracks 2 on the second side of the connection carrier 1 in combination thus form a second electrode 23. The contact tracks 2 of the second electrode 23 are aligned perpendicular to the contact tracks 2 to the two first electrodes 22. The exemplary embodiment shown in FIG. 11B, as in FIG. 11A, shows only semiconductor components 9 on a first side of the connection carrier 1. Alternatively, the second side may also have semiconductor components 9.

The exemplary embodiment shown in FIG. 11C corresponds essentially to the exemplary embodiment described in connection with FIG. 11B. In contrast, the connection carrier 1 has two contact tracks 2 on its second side, which electrically contact a further semiconductor component 9. In particular, the connection carrier 1 or the substrate 10 then comprises semiconductor components 9 on the two opposite sides of the connection carrier 1.

The contact tracks 2 on the first side of the connection carrier 1, which provide a capacitive tactile sensor function, are aligned perpendicular to the contact tracks 2 on the second side of the connection carrier 1. In particular, a plurality of parallel contact tracks 2 thus form a first electrode 22 and a further first electrode 22 on the first side. A plurality of parallel contact tracks 2 thus form a second electrode 23 and a further second electrode 23 on the second side. The first electrode 22 and the further first electrode 22 are arranged on the connection carrier 1 on the same side and in the same plane. The second electrode 23 and the further second electrode 23 are arranged on the connection carrier 1 on a second side in the same plane. In this case, the contact tracks 2 providing an electrical contacting of the semiconductor component 9 on the first side are arranged between the first electrode 22 and the further first electrode 22. Likewise, the contact tracks 2 providing electrical contacting of the semiconductor component 9 on the second side are arranged between the second electrode 23 and the further second electrode 23. The contact tracks 2 of the two first electrodes 22 are arranged perpendicular to and directly above the contact tracks 2 of the two second electrodes 23.

The invention is not limited by the description based on the exemplary embodiments. Rather, the invention comprises each new feature as well as any combination of features, which includes in particular every combination of features in the patent claims, even if this feature or this combination itself is not explicitly specified in the patent claims or the exemplary embodiments.

### LIST OF REFERENCE SIGNS

1 connection carrier
10 substrate
100 optoelectronic device
2 contact track
longitudinal extension axis
21 subregion
22 first electrode
23 second electrode
24 third electrode
25 reflection-reducing coating
27 current path
29 virtual intersection point
3 network structure
30 opening
31 first network tracks
32 second network tracks
33 peripheral region
4 contact surface
41 continuation
5 intervening gap
6 bridge
65 insulator
7 contact conductor
8 connection region
81 connection surface
9 semiconductor component
91 connection
d1 center distance
w1 width
h1 height

1. A connection carrier having at least one contact track which is connected in an electrically conductive manner to a contact surface for electrically contacting a semiconductor component, the contact track having a network structure with a plurality of network tracks in at least some locations, wherein the contact surface has a continuation which extends away from the contact surface.

2. The connection carrier as claimed in claim 1,
wherein the network tracks have a width between 2 μm and 20 μm inclusive.

3. The connection carrier as claimed in claim 1,
wherein the network tracks have a height between 1 μm and 8 μm inclusive.

4. The connection carrier as claimed in claim 1,
wherein the network structure is formed at least in some locations by first network tracks running parallel to one another and second network tracks running parallel to one another, wherein the first network tracks and the second network tracks run obliquely or perpendicular to each other.

5. The connection carrier as claimed in claim 4,
wherein a longitudinal extension axis of the contact track runs obliquely to the first network tracks and obliquely to the second network tracks, at least in some locations.

6. The connection carrier as claimed in claim 1,
wherein in a peripheral region of the network structure and in the direction away from the center of the network structure, a center distance between adjacent first network tracks and/or between adjacent second network tracks is gradually increased and/or the width of the network tracks is gradually reduced.

7. The connection carrier as claimed in claim 1,
wherein the contact surface is a flat electrically conductive region.

8. The connection carrier as claimed in claim 1,
wherein the contact surface overlaps with at least two network tracks of the network structure.

9. The connection carrier as claimed in claim 1,
wherein the contact surface has a continuation which extends away from the contact surface.

10. The connection carrier as claimed in claim 1,
wherein the length of the continuation is at least as large as a distance between the first network tracks and/or a distance between the second network tracks.

11. The connection carrier as claimed in claim 1,
wherein the network structure along the contact track forms at least two separate current paths within the contact track.

12. The connection carrier as claimed in claim 1,
wherein the contact track at least in some locations has a reflection-reducing coating, which in particular contains palladium or molybdenum or copper nitride.

13. The connection carrier as claimed in claim 1,
wherein at least one contact track provides an electrical contacting of the semiconductor component and/or wherein at least one contact track provides a capacitive tactile sensor function, wherein the at least one contact track providing the capacitive tactile sensor function is used for the control of the semiconductor component.

14. The connection carrier as claimed in claim 13, wherein at least one contact track is arranged on a first side and/or on a second side of the connection carrier facing away from the first side.

15. An optoelectronic device having a connection carrier as claimed in claim 1 and having an optoelectronic semiconductor component, wherein the optoelectronic semiconductor component is connected in an electrically conductive manner to at least two contact surfaces.

16. The optoelectronic device as claimed in claim 15,
wherein electrical connections of the optoelectronic semiconductor component are arranged on a side facing the connection carrier.

17. The optoelectronic device as claimed in claim 15,
wherein at least one electrical connection of the optoelectronic semiconductor component is arranged on a side facing away from the connection carrier and connected to the contact surfaces in an electrically conductive manner via a contact conductor.

18. A method for producing a connection carrier with contact tracks, having the steps:
a) providing a substrate; and
b) forming contact tracks, which have a network structure at least in some locations, on the substrate.

19. The method as claimed in claim 18,
wherein before step b) a continuous network structure is arranged on the substrate and the network structure is structured into the contact tracks in step b).

20. The method as claimed in claim 18,
wherein the network structure and the contact tracks are formed in a common method step.

21. The method as claimed in claim 18,
wherein contact surfaces are formed, which are connected in an electrically conductive manner to a contact track in each case.

22. The method as claimed in claim 18,
with which a connection carrier is produced, wherein the connection carrier includes at least one contact track which is connected in an electrically conductive manner to a contact surface for electrically contacting a semiconductor component, the contact track having a network structure with a plurality of network tracks in at least some locations, wherein the contact surface has a continuation which extends away from the contact surface.

23. The connection carrier as claimed in claim 1,
wherein the contact track is subdivided into two subregions at a virtual intersection point with a further contact track, wherein the subregions are connected to each other via an electrically conductive bridge, which is electrically insulated from the further contact track
